(19) United States
(12) Patent Application Publication
(10) Pub. No.: US 2015/0017782 A1
(43) Pub. Date: Jan. 15, 2015

(54) BONDING DEVICE AND BONDING METHOD

(71) Applicant: TOKYO ELECTRON LIMITED, Tokyo (JP)

(72) Inventors: Naoki AKIYAMA, Nirasaki-City (JP); Masahiko SUGIYAMA, Nirasaki-City (JP); Yosuke OMORI, Koshi City (JP); Shinji AKAIKE, Nirasaki-City (JP); Hideaki TANAKA, Nirasaki-City (JP); Masahiro YAMAMOTO, Tokyo (JP)

(21) Appl. No.: 14/325,685

(22) Filed: Jul. 8, 2014

(30) Foreign Application Priority Data
Jul. 10, 2013 (JP) 2013-144879

(51) Int. Cl. H01L 23/00

(52) U.S. Cl. CPC H01L 24/80; H01L 24/741
USPC 438/455; 156/556; 156/362

(57) ABSTRACT

A bonding device for bonding substrates together, includes: a first holding unit configured to hold a first substrate on a lower surface thereof; a second holding unit located below the first holding unit and configured to hold a second substrate on an upper surface thereof; a moving mechanism configured to move the first holding unit or the second holding unit in a horizontal direction and a vertical direction; a first image pickup unit located in the first holding unit and configured to pick up an image of the second substrate held in the second holding unit; and a second image pickup unit located in the second holding unit and configured to pick up an image of the first substrate held in the first holding unit, at least one of the first image pickup unit and the second image pickup unit including an infrared camera.

### CROSS-REFERENCE TO RELATED APPLICATION

This application claims the benefit of Japanese Patent Application No. 2013-144879, filed on Jul. 10, 2013, in the Japan Patent Office, the disclosure of which is incorporated herein in its entirety by reference.

### TECHNICAL FIELD

The present disclosure relates to a bonding device for bonding substrates together, and a bonding method.

### BACKGROUND

In recent years, semiconductor devices have been under high integration. When many highly-integrated semiconductor devices are arranged in a horizontal plane and are connected by wirings for final fabrication, there are problems of increase in wiring length, wiring resistance and wiring delay.

Under the circumstances, there has been proposed a three-dimensional integration technique for stacking semiconductor devices in three dimensions. This three-dimensional integration technique uses a bonding system to bond two semiconductor wafers (hereinafter abbreviated as “wafers”) together. For example, the bonding system includes a surface modifying device (surface activating device) for modifying bonding surfaces of the wafers, a surface hydrophilizing device for hydrophilizing the surfaces of the wafers modified by the surface modifying device and a bonding device for bonding the wafers having the surfaces hydrophilized by the surface hydrophilizing device. In this bonding system, the surface modifying device modifies the wafer surfaces by plasma-processing the wafer surfaces and the surface hydrophilizing device hydrophilizes the wafer surfaces by supplying pure water onto the wafer surfaces. Then, the bonding device bonds the wafers using a Van der Waals force and hydrogen bonding (an inter-molecular force).

In the bonding device, one wafer (hereinafter referred to as an “upper wafer”) is held by an upper chuck and another wafer (hereinafter referred to as a “lower wafer”) is held by a lower chuck installed below the upper chuck. In this state, the bonding device bonds the upper wafer and the lower wafer together. Prior to bonding the wafers in this way, the horizontal positions of the upper chuck and the lower chuck are adjusted. More specifically, a lower image pickup member, e.g., a visible light camera, is moved in the horizontal direction in order for the lower image pickup member to pick up an image of the front surface of the upper wafer held in the upper chuck. An upper image pickup member, e.g., a visible light camera, is moved in the horizontal direction in order for the upper image pickup member to pick up an image of the front surface of the lower wafer held in the lower chuck. The horizontal positions of the upper chuck and the lower chuck are adjusted such that the reference point of an upper wafer surface and the reference point of a lower wafer surface coincide with each other.

In recent years, there is a demand for bonding three or more wafers in a bonding device. In this case, for example, a lower wafer to be bonded has a configuration in which two wafers are laminated in advance. In such a case, a reference point exists on a bonding surface of two wafers which constitute the lower wafer. That is to say, the reference point exists within the lower wafer and does not exist on the front surface of the lower wafer. For that reason, in the aforementioned method, it is not possible to pick up an image of a reference point of an overlapped wafer with the upper image pickup member and the lower image pickup member. It is therefore impossible to adjust the horizontal positions of the upper chuck and the lower chuck. Thus, there is a fear that the horizontal positions of the wafers to be bonded will be out of alignment.

Furthermore, after an upper wafer and a lower wafer are bonded together, it is desirable to inspect the bonding accuracy of the bonded wafer (hereinafter referred to as an “overlapped wafer”), namely the accuracy of the relative position of the upper wafer and the lower wafer bonded together. In the inspection of the overlapped wafer, inspection is conducted, e.g., as to whether the reference point of the upper wafer and the reference point of the lower wafer coincide with each other. However, in the overlapped wafer, the reference point exists on a bonding surface of the wafers. That is to say, the reference point exists within the lower wafer and does not exist on the front surface of the overlapped wafer. For that reason, it is not possible to pick up an image of the reference point of the overlapped wafer with the upper image pickup member and the lower image pickup member. It is therefore impossible to conduct the inspection of the overlapped wafer. Thus, there is a fear that the horizontal positions of the wafers to be bonded will be out of alignment.

In order to conduct the inspection of the overlapped wafer, it may be desirable to use an inspection device additionally installed outside a bonding device. However, it is costly to additionally install the inspection device. Moreover, time is required from the bonding process performed in the bonding device to the inspection conducted in the inspection device. This makes it impossible to provide timely feed back on the inspection result for the subsequent bonding process.

As set forth above, it is likely that the horizontal positions of the wafers to be bonded will be out of alignment. Accordingly, there is room for improvement in the bonding process of the wafers.

### SUMMARY

Some embodiments of the present disclosure provide a bonding device and a bonding method capable of appropriately adjusting the horizontal positions of a first holding unit for holding a first substrate and a second holding unit for holding a second substrate and capable of appropriately performing a bonding process of substrates.

In accordance with an aspect of the present disclosure, there is provided a bonding device for bonding substrates together, including: a first holding unit configured to hold a first substrate on a lower surface of the first holding unit; a second holding unit located below the first holding unit and configured to hold a second substrate on an upper surface of the second holding unit; a moving mechanism configured to move the first holding unit or the second holding unit in a horizontal direction and a vertical direction; a first image pickup unit located in the first holding unit and configured to pick up an image of the second substrate held in the second holding unit; and a second image pickup unit located in the second holding unit and configured to pick up an image of the first substrate held in the first holding unit, at least one of the first image pickup unit and the second image pickup unit including an infrared camera.

In accordance with another aspect of the present disclosure, there is provided a bonding method for bonding substrates with a bonding device which includes a first holding unit configured to hold a first substrate on a lower surface of the first holding unit, a second holding unit located below the first holding unit and configured to hold a second substrate on an upper surface of the second holding unit, a moving mechanism configured to move the first holding unit or the second holding unit in a horizontal direction and a vertical direction, a first image pickup unit located in the first holding unit and configured to pick up an image of the second substrate held in the second holding unit, and a second image pickup unit located in the second holding unit and configured to pick up an image of the first substrate held in the first holding unit, at least one of the first image pickup unit and the second image pickup unit including an infrared camera. The method includes: picking up images of the second substrate not yet bonded and the first substrate not yet bonded by the first image pickup unit and the second image pickup unit, respectively; and adjusting horizontal positions of the first holding unit and the second holding unit by the moving mechanism based on the images thus picked up.

In accordance with another aspect of the present disclosure, there is provided a bonding method for bonding substrates with a bonding device which includes a first holding unit configured to hold a first substrate on a lower surface of the first holding unit, a second holding unit located below the first holding unit and configured to hold a second substrate on an upper surface of the second holding unit, a moving mechanism configured to move the first holding unit or the second holding unit in a horizontal direction and a vertical direction, a first image pickup unit located in the first holding unit and configured to pick up an image of the second substrate held in the second holding unit, and a second image pickup unit located in the second holding unit and configured to pick up an image of the first substrate held in the first holding unit, at least one of the first image pickup unit and the second image pickup unit including an infrared camera. The method includes: obtaining an image for inspection of an overlapped substrate obtained by bonding the first substrate and the second substrate using the infrared camera; and adjusting horizontal positions of the first holding unit and the second holding unit with the moving mechanism based on the image for inspection obtained from the infrared camera.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view showing a schematic configuration of a bonding system according to the present embodiment.

FIG. 2 is a side view showing a schematic internal configuration of the bonding system according to the present embodiment.

FIG. 3 is a side view showing schematic configurations of an upper wafer and a lower wafer.

FIG. 4 is a horizontal sectional view showing a schematic configuration of a bonding device.

FIG. 5 is a vertical sectional view showing the schematic configuration of the bonding device.

FIG. 6 is a side view showing a schematic configuration of a position adjusting mechanism.

FIG. 7 is a plan view showing a schematic configuration of an inverting mechanism.

FIG. 8 is a side view showing the schematic configuration of the inverting mechanism.

FIG. 9 is another side view showing the schematic configuration of the inverting mechanism.

FIG. 10 is a side view showing schematic configurations of a holding arm and a holding member.

FIG. 11 is a side view showing a schematic internal configuration of the bonding device.

FIG. 12 is an explanatory view showing a schematic configuration of an upper image pickup unit.

FIG. 13 is an explanatory view showing a schematic configuration of a lower image pickup unit.

FIG. 14 is a vertical sectional view showing schematic configurations of an upper chuck and a lower chuck.

FIG. 15 is a plan view of the upper chuck seen from below.

FIG. 16 is a plan view of the lower chuck seen from above.

FIG. 17 is a flowchart illustrating major steps of a wafer bonding process.

FIG. 18 is an explanatory view illustrating how to adjust the horizontal positions of the upper image pickup unit and the lower image pickup unit.

FIG. 19 is an explanatory view illustrating how to adjust the horizontal positions of the upper chuck and the lower chuck.

FIG. 20 is another explanatory view illustrating how to adjust the horizontal positions of the upper chuck and the lower chuck.

FIG. 21 is an explanatory view illustrating how to adjust the vertical positions of the upper chuck and the lower chuck.

FIG. 22 is an explanatory view illustrating how to bring the central portion of the upper wafer into contact with the central portion of the lower wafer and how to press the central portion of the upper wafer against the central portion of the lower wafer.

FIG. 23 is an explanatory view illustrating how to sequentially bring the upper wafer into contact with the lower wafer.

FIG. 24 is an explanatory view showing a state where the front surface of the upper wafer is brought into contact with the front surface of the lower wafer.

FIG. 25 is an explanatory view showing a state where the upper wafer is bonded to the lower wafer.

FIG. 26 is an explanatory view illustrating how to inspect an overlapped wafer.

FIG. 27 is another explanatory view illustrating how to inspect the overlapped wafer.

FIG. 28 is an explanatory view illustrating how to adjust the horizontal positions of the upper image pickup unit and the lower image pickup unit in another embodiment.

FIG. 29 is an explanatory view illustrating how to adjust the horizontal positions of the upper chuck and the lower chuck in another embodiment.

FIG. 30 is an explanatory view illustrating how to inspect an overlapped wafer in another embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

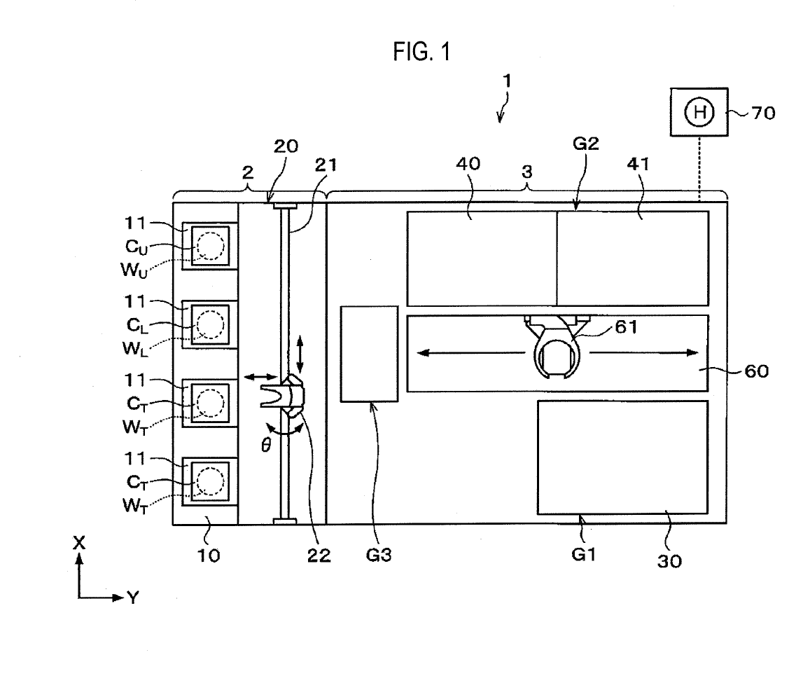

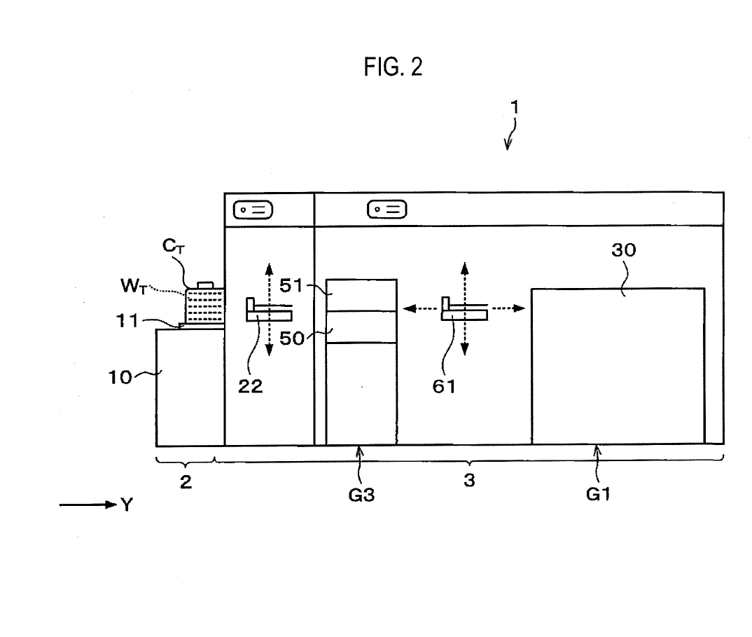

Embodiments of the present disclosure will now be described in detail. FIG. 1 is a plan view showing a schematic configuration of a bonding system 1 according to the present embodiment. FIG. 2 is a side view showing a schematic internal configuration of the bonding system 1.

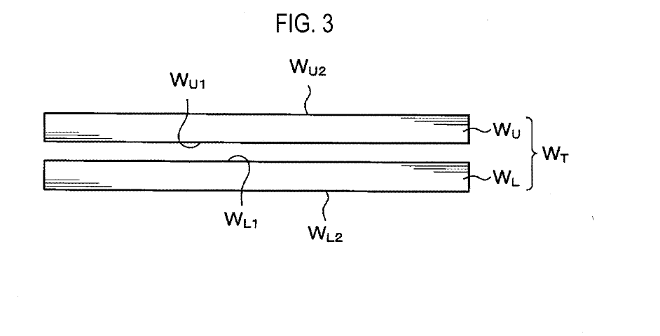

The bonding system 1 is used to bond two substrates, for example, wafers W_{U} and W_{L}, together, as shown in FIG. 3. In the following description, a wafer arranged at the upper side is referred to as an “upper wafer W_{U}” which serves as a first substrate and a wafer arranged at the lower side is referred to as a “lower wafer W_{L}” which serves as a second substrate. Moreover, the bonding surface of the upper wafer W_{U} bonded to the lower wafer W_{L} is referred to as a “front surface W_{U1},” whereas the surface opposite to the front surface W_{U1} is referred to as a “rear surface W_{U2}.” Similarly, the bonding surface of the lower wafer W_{L} bonded to the upper wafer W_{U} is referred to as a “front surface W_{L1},” whereas the surface opposite to the front surface W_{L1} is referred to as a “rear surface W_{L2}.” In addition, in the bonding system 1, an overlapped wafer W_{T} serving as an overlapped substrate is formed by bonding the upper wafer W_{U} and the lower wafer W_{L}.

As shown in FIG. 1, the bonding system 1 includes a carry-in/carry-out station 2 and a processing station 3 which are integratedly connected to each other. Cassettes C_{U}, C_{L}, and C_{T} respectively capable of accommodating a plurality of wafers W_{U} and W_{L} and a plurality of overlapped wafers W_{T} are carried into the carry-in/carry-out station 2 and are carried out of the carry-in/carry-out station 2. The processing station 3 is provided with various types of processing devices which implement predetermined processes with respect to the wafers W_{U} and W_{L} and the overlapped wafers W_{T}.

A cassette mounting table 10 is installed in the carry-in/carry-out station 2. A plurality of, e.g., four, cassette mounting boards 11 are installed in the cassette mounting table 10. The cassette mounting boards 11 are arranged in a line along a horizontal X-direction (an up-down direction in FIG. 1). The cassettes C_{U}, C_{L} and C_{T} can be mounted on the cassette mounting boards 11 when carrying the cassettes C_{U}, C_{L} and C_{T} into the bonding system 1 and carrying the cassettes C_{U}, C_{L} and C_{T} out of the bonding system 1. In this way, the carry-in/carry-out station 2 is configured to hold the upper wafers W_{U}, the lower wafers W_{L} and the overlapped wafers W_{T}. The number of the cassette mounting boards 11 is not limited to the present embodiment but may be arbitrarily determined. One of the cassettes may be used as a collection cassette for collecting defective wafers. That is to say, the collection cassette is a cassette by which the defective wafers each having a defect caused by various factors when bonding the upper wafer W_{U} and the lower wafer W_{L} can be separated from other normal overlapped wafers W_{T}. In the present embodiment, one of cassettes C_{T} is used as the collection cassette for collecting the defective wafers, and other cassettes C_{T} are used to accommodate the normal overlapped wafers W_{T}.

In the carry-in/carry-out station 2, a wafer transfer part 20 is installed adjacent to the cassette mounting table 10. A wafer transfer device 22 movable along a transfer path 21 extending in the X-direction is installed in the wafer transfer part 20. The wafer transfer device 22 is movable in a vertical direction and about a vertical axis (in a θ direction) and is capable of transferring the upper wafer W_{U}, the lower wafer W_{L} and the overlapped wafer W_{T} between the cassettes C_{U}, C_{L} and C_{T} mounted on the respective cassette mounting boards 11 and the below-mentioned transition devices 50 and 51 of a third processing block G3 of the processing station 3.

A plurality of, e.g., three, processing blocks G1, G2 and G3 provided with various types of devices are installed in the processing station 3. For example, the first processing block G1 is installed at the front side of the processing station 3 (at the negative side in the X-direction in FIG. 1), and the second processing block G2 is installed at the back side of the processing station 3 (at the positive side in the X-direction in FIG. 1). The third processing block G3 is installed at the side of the carry-in/carry-out station 2 in the processing station 3 (at the negative side in a Y-direction in FIG. 1).

For example, a surface modifying device 30 configured to modify the front surfaces W_{U1} and W_{L1} of the upper and lower wafers W_{U} and W_{L} is arranged in the first processing block G1. In the surface modifying device 30, an oxygen gas as a process gas is excited, converted to plasma and ionized under, e.g., a depressurized atmosphere. The oxygen ions are irradiated on the front surfaces W_{U1} and W_{L1}, whereby the front surfaces W_{U1} and W_{L1} are plasma-processed and modified.

For example, in the second processing block G2, a surface hydrophilizing device 40 configured to hydrophilize and clean the front surfaces W_{U1} and W_{L1} of the upper and lower wafers W_{U} and W_{L} using, e.g., pure water, and a bonding device 41 configured to bond the upper and lower wafers W_{U} and W_{L} are arranged side by side in the named order from the side of the carry-in/carry-out station 2 along the horizontal Y-direction.

In the surface hydrophilizing device 40, pure water is supplied onto the upper and lower wafers W_{U} and W_{L} while rotating the upper and lower wafers W_{U} and W_{L} held in, e.g., a spin chuck. The pure water thus supplied is diffused on the front surfaces W_{U1} and W_{L1} of the upper and lower wafers W_{U} and W_{L}, whereby the front surfaces W_{U1} and W_{L1} are hydrophilized. The configuration of the bonding device 41 will be described later.

For example, in the third processing block G3, transition devices 50 and 51 for the upper and lower wafers W_{U} and W_{L} and the overlapped wafers W_{T} are installed in two stages one above another from below as shown in FIG. 2.

As shown in FIG. 1, a wafer transfer region 60 is formed in an area surrounded by the first processing block G1, the second processing block G2 and the third processing block G3. For example, a wafer transfer device 61 is arranged in the wafer transfer region 60.

The wafer transfer device 61 includes a transfer arm which can move, e.g., in the vertical direction (in the Z-direction), in the horizontal direction (in the Y-direction and the X-direction) and about the vertical axis. The wafer transfer device 61 can move within the wafer transfer region 60 and can transfer the upper and lower wafers W_{U} and W_{L} and the overlapped wafer W_{T} to a specified device existing within the first processing block G1, the second processing block G2 or the third processing block G3 disposed around the wafer transfer region 60.

As shown in FIG. 1, a control unit 70 is installed in the bonding system 1 described above. The control unit 70 is, e.g., a computer, and is provided with a program storage unit (not shown). The program storage unit stores a program that controls the processing of the upper and lower wafers W_{U} and W_{L} and the overlapped wafer W_{T} performed in the bonding system 1. Furthermore, the program storage unit stores a program for controlling the operations of drive systems for various types of processing devices and the transfer device described above to realize the below-mentioned wafer bonding process in the bonding system 1. The aforementioned programs may be recorded in a computer-readable storage medium H such as, e.g., a hard disc (HD), a flexible disc (FD), a compact disc (CD), a magneto-optical disc (MO) or a memory card and installed in the control unit 70 from the storage medium H.

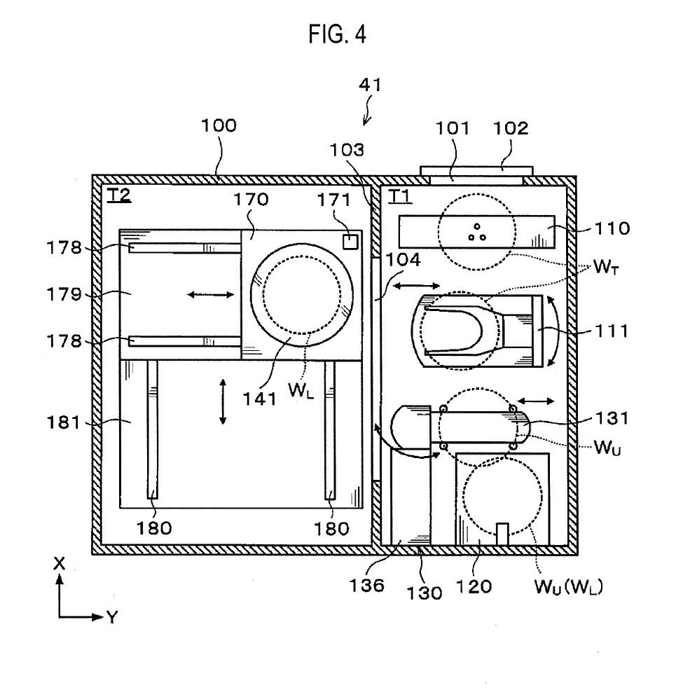

Next, description will be made on the configuration of the aforementioned bonding device 41. As shown in FIG. 4, the bonding device 41 includes a processing vessel 100, the interior of which is hermetically sealable. A carry-in/carry-out gate 101 through which the upper and lower wafers W_{U} and W_{L} and the overlapped wafer W_{T} are carried is formed on the side surface of the processing vessel 100 adjoining the wafer transfer region 60. An opening/closing shutter 102 is installed in the carry-in/carry-out gate 101.

The interior of the processing vessel 100 is divided into a transfer region T1 and a processing region T2 by an internal wall 103. The carry-in/carry-out gate 101 is formed on the side surface of the processing vessel 100 corresponding to the transfer region T1. A carry-in/carry-out gate 104 through which the upper and lower wafers W_{U} and W_{L} and the overlapped wafer W_{T} are carried is also formed in the internal wall 103.

A transition 110 is located at the X-direction positive side of the transfer region T1 for temporarily mounting the upper and lower wafers W_{U} and W_{L} and the overlapped wafer W_{T}. The transitions 110 is installed in, e.g., two stages, and are capable of simultaneously mounting two of the upper and lower wafers W_{U} and W_{L} and the overlapped wafer W_{T}.

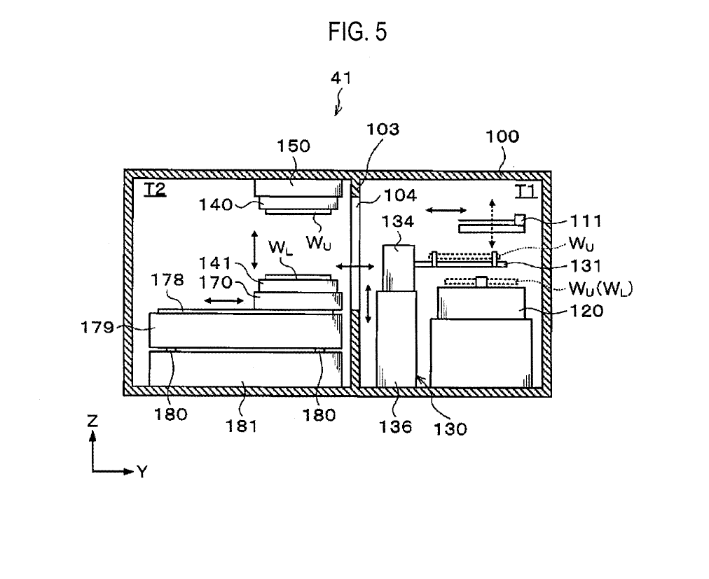

A wafer transfer mechanism 111 is installed in the transfer region T1. As shown in FIGS. 4 and 5, the wafer transfer mechanism 111 includes a transfer arm which can move, e.g., in the vertical direction (in the Z-direction), in the horizontal direction (in the Y-direction and the X-direction) and about the vertical axis. The wafer transfer mechanism 111 is capable of transferring the upper and lower wafers W_{U} and W_{L} and the overlapped wafer W_{T} within the transfer region T1 or between the transfer region T1 and the processing region T2.

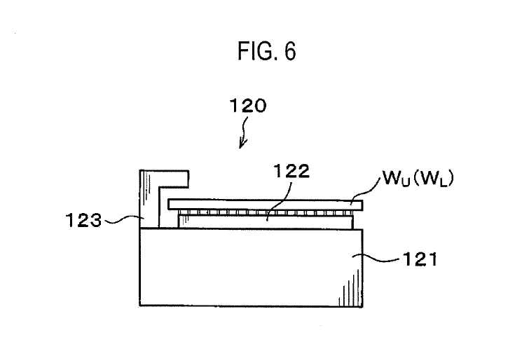

A position adjustment mechanism 120 configured to adjust the horizontal direction orientations of the upper and lower wafers W_{U} and W_{L} is located in the X-direction negative side of the transfer region T1. As shown in FIG. 6, the position adjustment mechanism 120 includes a base 121, a holding unit 122 configured to hold the upper or lower wafer W_{U} or W_{L} with a pin chuck system and to rotate the upper or lower wafer W_{U} or W_{L}, and a detecting unit 123 configured to detect the position of a notch portion of the upper or lower wafer W_{U} or W_{L}. The pin chuck system employed in the holding unit 122 is the same as the pin chuck system employed in an upper chuck 140 and a lower chuck 141 to be described later and, therefore, will not be described here. In the position adjustment mechanism 120, the detecting unit 123 detects the position of the notch portion of the upper or lower wafer W_{U} or W_{L} while rotating the upper or lower wafer W_{U} or W_{L} held in the holding unit 122, and adjusts the position of the notch portion of the upper or loser wafer W_{U} or W_{L}. Thus, the position adjustment mechanism 120 adjusts the horizontal direction orientation of the upper or lower wafer W_{U} or W_{L}.

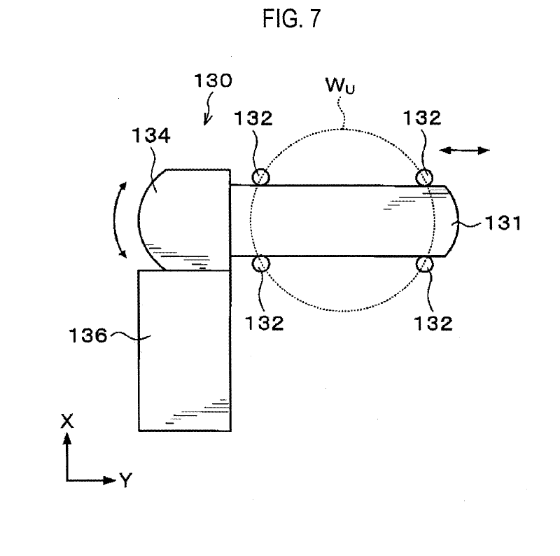

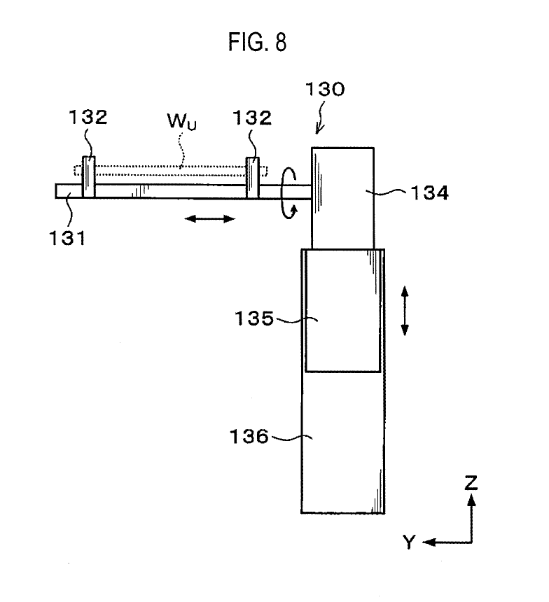

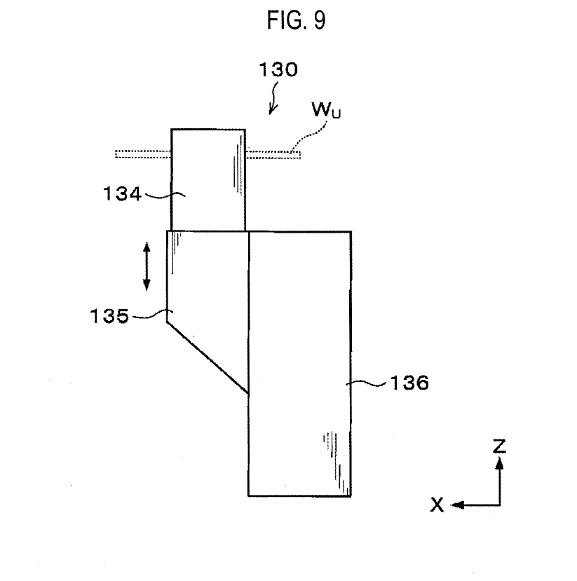

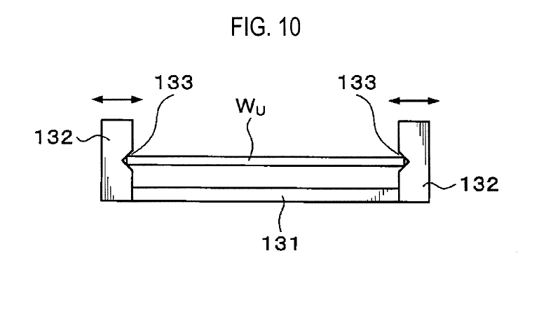

In the transfer region T1, as shown in FIGS. 4 and 5, there is also installed an inverting mechanism 130 configured to invert the front and rear surfaces of the upper wafer W_{U}. As shown in FIGS. 7 to 9, the inverting mechanism 130 includes a holding arm 131 configured to hold the upper wafer W_{U}. The holding arm 131 extends in the horizontal direction (in the Y-direction in FIGS. 7 and 8). In the holding arm 131, holding members 132 configured to hold the upper wafer W_{U} are installed at, e.g., four points. As shown in FIG. 10, the holding members 132 are configured to move in the horizontal direction with respect to the holding arm 131. Cutouts 133 for holding the outer peripheral portion of the upper wafer W_{U} are formed on the side surfaces of the holding members 132. The holding members 132 can hold the upper wafer W_{U} interposed therebetween by inserting the outer peripheral portion of the upper wafer W_{U} into the cutouts 133.

As shown in FIGS. 7 to 9, the holding arm 131 is supported by a first drive unit 134 provided with, e.g., a motor and the like. The holding arm 131 can be rotated about a horizontal axis by the first drive unit 134. The holding arm 131 is not only rotatable about the first drive unit 134 but also movable in the horizontal direction (in the Y-direction in FIGS. 7 and 8). A second drive unit 135 provided with, e.g., a motor and the like, is installed below the first drive unit 134. By virtue of the second drive unit 135, the first drive unit 134 can be moved in the vertical direction along a support post 136 extending in the vertical direction. Thus, the upper wafer W_{U} held in the holding members 132 can be rotated about the horizontal axis and can be moved in the vertical direction and the horizontal direction by the first drive unit 134 and the second drive unit 135. The upper wafer W_{U} held in the holding members 132 can swing about the first drive unit 134 to move between the position adjustment mechanism 120 and the upper chuck 140 which will be described later.

As shown in FIGS. 4 and 5, the upper chuck 140 is located in the processing region T2 as a first holding unit that adsorptively holds the upper wafer W_{U} on the lower surface thereof and the lower chuck 141 as a second holding unit that mounts and adsorptively holds the lower wafer W_{L} on the upper surface thereof. The lower chuck 141 is located below the upper chuck 140 and is arranged to face the upper chuck 140. That is to say, the upper wafer W_{U} held in the upper chuck 140 and the lower wafer W_{L} held in the lower chuck 141 can be arranged to face each other.

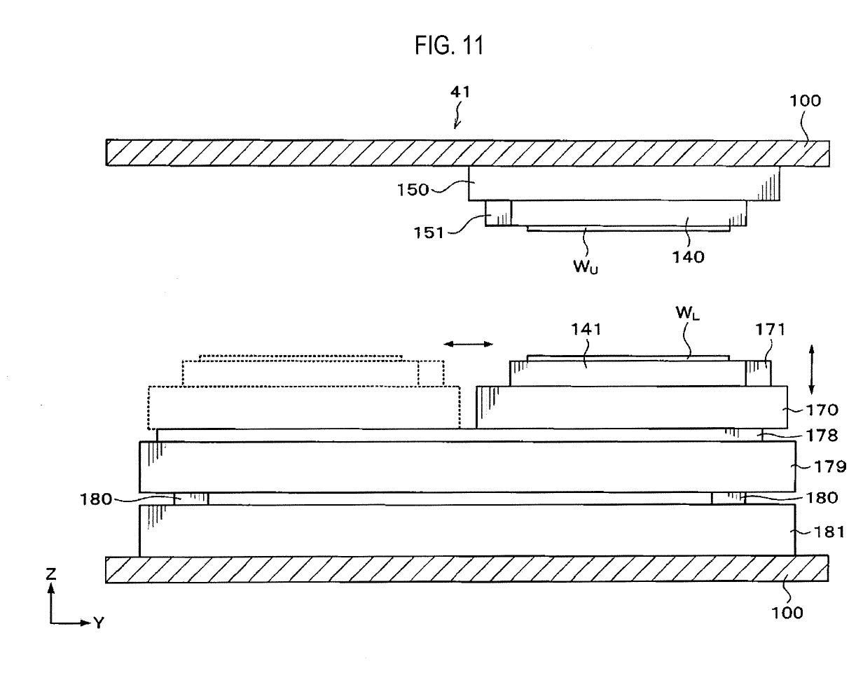

As shown in FIGS. 4, 5 and 11, the upper chuck 140 is supported by an upper chuck support unit 150 located above the upper chuck 140. The upper chuck support unit 150 is located on the ceiling surface of the processing vessel 100. That is to say, the upper chuck 140 is fixed to and installed in the processing vessel 100 through the upper chuck support unit 150.

An upper image pickup unit 151 is located in the upper chuck support unit 150 as a first image pickup unit for picking up an image of the front surface W_{L1} of the lower wafer W_{L} held in the lower chuck 141. That is to say, the upper image pickup unit 151 is located adjacent to the upper chuck 140.

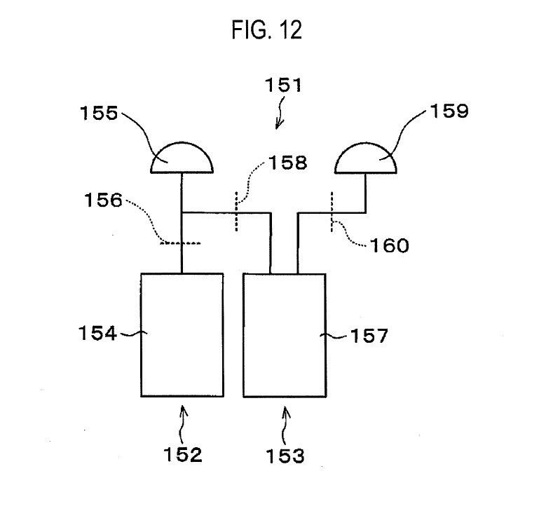

As shown in FIG. 12, the upper image pickup unit 151 includes an infrared camera 152 and a visible light camera 153. The infrared camera 152 is a camera that acquires an infrared image. More specifically, the infrared camera 152 includes a sensor 154, a micro lens 155 connected to the sensor 154, and a shutter 156 installed between the sensor 154 and the micro lens 155. The visible light camera 153 is a camera that acquires a visible light image. More specifically, the visible light camera 153 includes a sensor 157, a micro lens 155 connected to the sensor 157, a shutter 158 installed between the sensor 157 and the micro lens 155, a macro lens 159 connected to the sensor 157, and a shutter 160 installed between the sensor 157 and the macro lens 159. The micro lens 155 is common to the infrared camera 152 and the visible light camera 153. The macro lens 159, which has an image pickup range of 6.4 mm×4.8 mm, is capable of picking up an image over a wide range but has low resolution. The micro lens 155, which has an image pickup range of 0.55 mm×0.4 mm, is narrow in image pickup range but has high resolution.

By opening and closing the shutters 156, 158 and 160, the upper image pickup unit 151 can perform an image pickup operation using the micro lens 155 of the infrared camera 152, an image pickup operation using the micro lens 155 of the visible light camera 153 and an image pickup operation using the macro lens 159 of the visible light camera 153.

As shown in FIGS. 4, 5 and 11, the lower chuck 141 is supported on a first lower chuck moving unit 170 installed below the lower chuck 141. As will be described later, the first lower chuck moving unit 170 is configured to move the lower chuck 141 in the horizontal direction (the Y-direction). Moreover, the first lower chuck moving unit 170 is configured to move the lower chuck 141 in the vertical direction and to rotate the lower chuck 141 about the vertical axis.

A lower image pickup unit 171 is located in the first lower chuck moving unit 170 as a second image pickup unit for picking up an image of the front surface W_{U1} of the upper wafer W_{U} held in the upper chuck 140. That is to say, the lower image pickup unit 171 is located adjacent to the lower chuck 141.

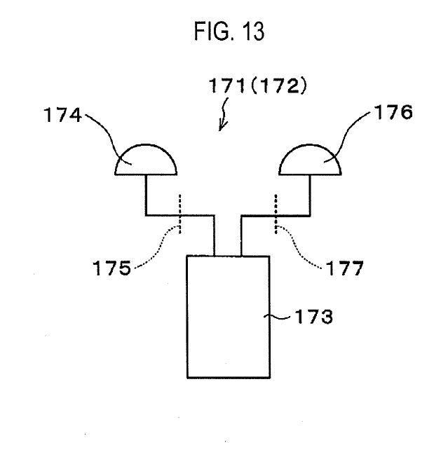

As shown in FIG. 13, the lower image pickup unit 171 includes a visible light camera 172. More specifically, the visible light camera 172 includes a sensor 173, a micro lens 174 connected to the sensor 173, a shutter 175 installed between the sensor 173 and the micro lens 174, a macro lens 176 connected to the sensor 173, and a shutter 177 installed between the sensor 173 and the macro lens 176. The micro lens 174 and the macro lens 176 of the lower image pickup unit 171 are respectively identical to the micro lens 155 and the macro lens 159 of the upper image pickup unit 151 and, therefore, will not be described here.

By opening and closing the shutters 175 and 177, the lower image pickup unit 171 can perform an image pickup operation using the micro lens 174 and an image pickup operation using the macro lens 176.

As shown in FIGS. 4, 5 and 11, the first lower chuck moving unit 170 is located on a pair of rails 178 located at the lower surface side of the first lower chuck moving unit 170 and extending in the horizontal direction (the Y-direction). The first lower chuck moving unit 170 is configured to move along the rails 178.

The rails 178 are arranged in a second lower chuck moving unit 179. The second lower chuck moving unit 179 is located on a pair of rails 180 located at the lower surface side of the second lower chuck moving unit 179 and extending in the horizontal direction (the X-direction). The second lower chuck moving unit 179 is configured to move along the rails 180. That is to say, the second lower chuck moving unit 166 is configured to move the lower chuck 141 in the horizontal direction (the X-direction). The rails 180 are arranged on a mounting table 181 located on the bottom surface of the processing vessel 100.

In the present embodiment, the first lower chuck moving unit 170 and the second lower chuck moving unit 179 constitute a moving mechanism of the present disclosure.

Next, description will be made on the detailed configuration of the upper chuck 140 and the lower chuck 141 of the bonding device 41.

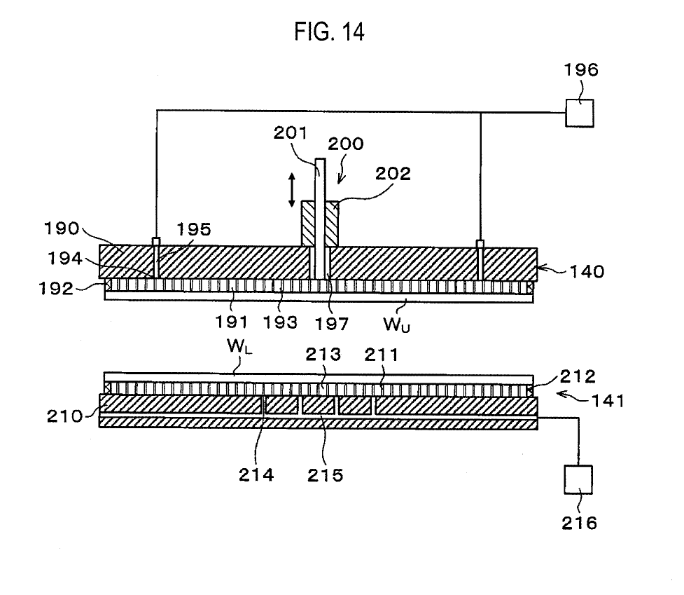

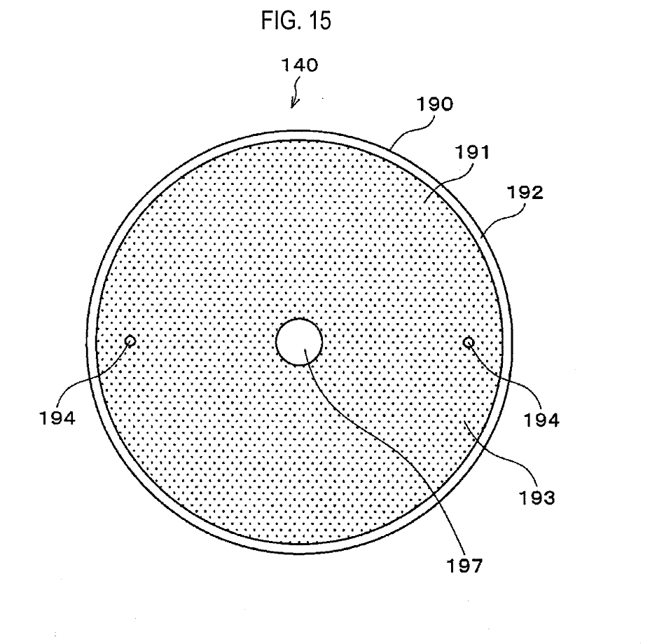

As shown in FIGS. 14 and 15, a pin chuck system is employed in the upper chuck 140. The upper chuck 140 includes a body portion 190 having a diameter larger than the diameter of the upper wafer W_{U} when seen in a plan view. A plurality of pins 191 which makes contact with the rear surface W_{U2} of the upper wafer W_{U} is installed on the lower surface of the body portion 190. Moreover, an outer wall portion 192 configured to support the outer peripheral portion of the rear surface W_{U2} of the upper wafer W_{U} is installed on the lower surface of the body portion 190. The outer wall portion 192 is annularly installed at the outer side of the pins 191.

Suction holes 194 for vacuum-drawing the upper wafer W_{U} in an inner region 193 of the outer wall portion 192 (hereinafter sometimes referred to as a “suction region 193”) are formed on the lower surface of the body portion 190. The suction holes 194 are formed at, e.g., two points, in the outer peripheral portion of the suction region 193. Suction pipes 195 installed within the body portion 190 are connected to the suction holes 194. A vacuum pump 196 is connected to the suction pipes 195 through joints.

The suction region 193 surrounded by the upper wafer W_{U}, the body portion 190 and the outer wall portion 192 is vacuum-drawn from the suction holes 194, whereby the suction region 193 is depressurized. At this time, the external atmosphere of the suction region 193 is kept at atmospheric pressure. Thus, the upper wafer W_{U} is pressed by the atmospheric pressure toward the suction region 193 just as much as the depressurized amount. Consequently, the upper wafer W_{U} is sucked and held by the upper chuck 140.

In this case, it is possible to reduce the flatness of the lower surface of the upper chuck 140 because the pins 191 are uniform in height. By making the lower surface of the upper chuck 140 (by reducing the flatness of the lower surface of the upper chuck 140) flat in this manner, it is possible to suppress vertical distortion of the upper wafer W_{U} held in the upper chuck 140. Since the rear surface W_{U2} of the upper wafer W_{U} is supported on the pins 191, the upper wafer W_{U} is easily detached from the upper chuck 140 upon releasing the vacuum-drawing of the upper wafer W_{U} performed by the upper chuck 140.

A through-hole 197 extending through the body portion 190 in the thickness direction is formed in the central portion of the body portion 190. The central portion of the body portion 190 corresponds to the central portion of the upper wafer W_{U} adsorptively held by the upper chuck 140. A pressing pin 201 of a pressing member 200 to be described below is inserted into the through-hole 197.

The pressing member 200 configured to press the central portion of the upper wafer W_{U} is installed on the upper surface of the upper chuck 140. The pressing member 200 has a cylindrical structure. The pressing member 200 includes the pressing pin 201 and an outer cylinder 202 serving as a guide when the pressing pin 201 is moved up and down. By virtue of a drive unit (not shown) provided with, e.g., a motor therein, the pressing pin 201 can be moved up and down in the vertical direction through the through-hole 197. When bonding the upper and lower wafers W_{U} and W_{L} in the below-mentioned manner, the pressing member 200 can bring the central portion of the upper wafer W_{U} into contact with the central portion of the lower wafer W_{L} and can press the central portion of the upper wafer W_{U} against the central portion of the lower wafer W_{L}.

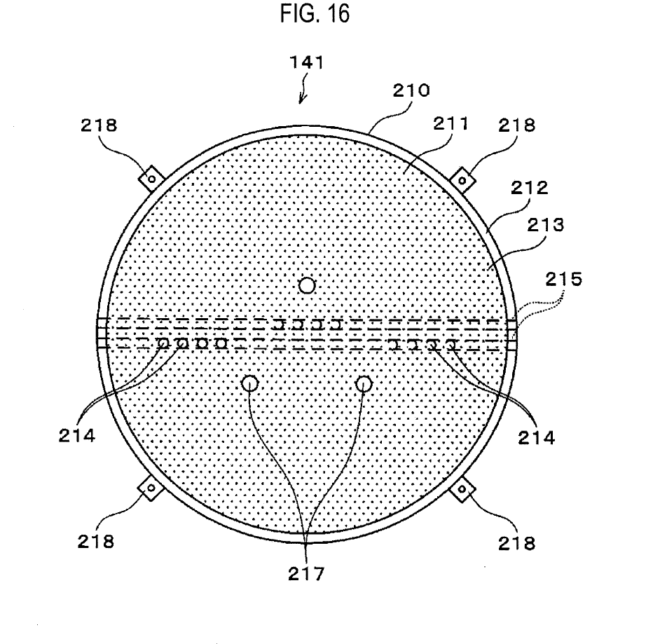

As shown in FIGS. 14 and 16, just like the upper chuck 140, the lower chuck 141 employs a pin chuck system. The lower chuck 141 includes a body portion 210 having a diameter larger than the diameter of the lower wafer W_{L} when seen in a plan view. A plurality of pins 211 which makes contact with the rear surface W_{L2} of the lower wafer W_{L} is installed on the upper surface of the body portion 210. Moreover, an outer wall portion 212 configured to support the outer peripheral portion of the rear surface W_{L2} of the lower wafer W_{L} is installed on the upper surface of the body portion 210. The outer wall portion 212 is annularly installed at the outer side of the pins 211.

Suction holes 214 for vacuum-drawing the lower wafer W_{L} in an inner region 213 of the outer wall portion 212 (hereinafter sometimes referred to as a “suction region 213”) are formed on the upper surface of the body portion 210. Suction pipes 215 installed within the body portion 210 are connected to the suction holes 214. For example, two suction pipes 215 are installed within the body portion 210. A vacuum pump 216 is connected to the suction pipes 215.

The suction region 213 surrounded by the lower wafer W_{L}, the body portion 210 and the outer wall portion 212 is vacuum-drawn from the suction holes 214, whereby the suction region 213 is depressurized. At this time, the external atmosphere of the suction region 213 is kept at atmospheric pressure. Thus, the lower wafer W_{L} is pressed by the atmospheric pressure toward the suction region 213 just as much as the depressurized amount. Consequently, the lower wafer W_{L} is adsorptively held by the lower chuck 141.

In this case, it is possible to reduce the flatness of the upper surface of the lower chuck 141 because the pins 211 are uniform in height. In addition, for example, even if particles exist within the processing vessel 100, it is possible to suppress the existence of particles on the upper surface of the lower chuck 141 when the interval of the adjoining pins 211 is appropriate. By making the upper surface of the lower chuck 141 (by reducing the flatness of the upper surface of the lower chuck 141) flat in this manner, it is possible to suppress vertical distortion of the lower wafer W_{L} held in the lower chuck 141. Since the rear surface W_{L2} of the lower wafer W_{L} is supported on the pins 211, the lower wafer W_{L} is easily detached from the lower chuck 141 upon releasing the vacuum-drawing of the lower wafer W_{L} performed by the lower chuck 141.

Through-holes 217 extending through the body portion 210 in the thickness direction are formed at, e.g., three points, in and around the central portion of the body portion 210. Lift pins installed below the first lower chuck moving unit 170 are inserted into the through-holes 217.

Guide members 218 configured to prevent the upper or lower wafer W_{U} or W_{L} or the overlapped wafer W_{T} from jumping out and sliding down from the lower chuck 141 are installed in the outer peripheral portion of the body portion 210. The guide members 218 are installed at a plurality of points, e.g., four points, at a regular interval in the outer peripheral portion of the body portion 210.

The operations of the respective parts of the bonding device 41 are controlled by the aforementioned control unit 70.

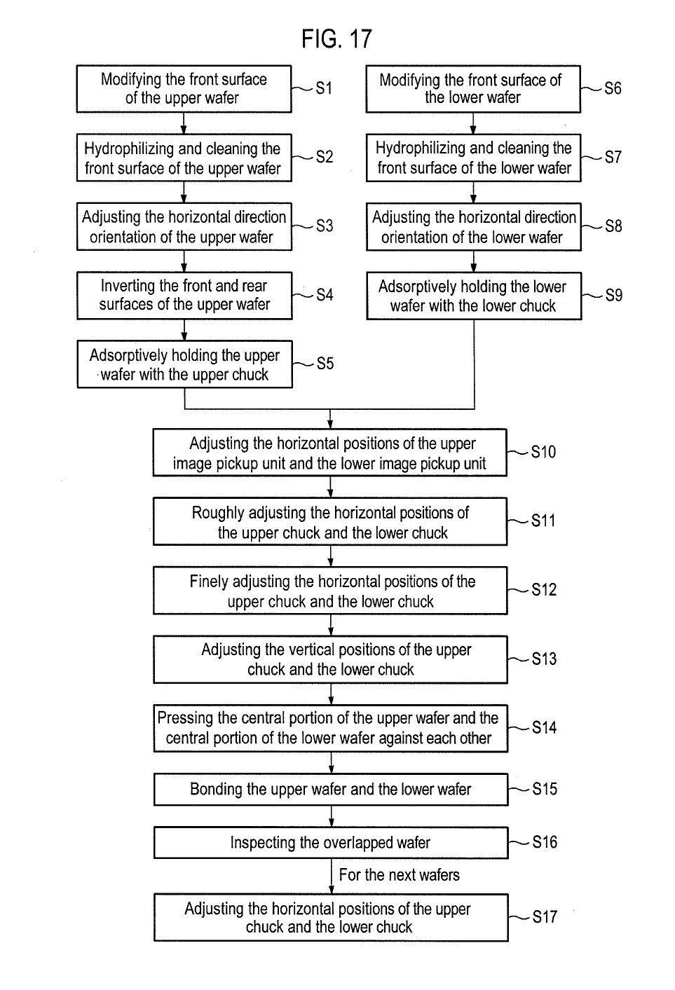

Next, description will be made on a process of bonding the upper and lower wafers W_{U} and W_{L} performed by the bonding system 1 configured as above. FIG. 17 is a flowchart illustrating examples of major steps of the wafer bonding process.

First, the cassette C_{U} accommodating a plurality of upper wafers W_{U}, the cassette C_{L} accommodating a plurality of lower wafers W_{L} and the empty cassette C_{T} are mounted on the specified cassette mounting boards 11 of the carry-in/carry-out station 2. Thereafter, the upper wafer W_{U} is taken out from the cassette C_{U} by the wafer transfer device 22 and is transferred to the transition device 50 of the third processing block G3 of the processing station 3.

Then, the upper wafer W_{U} is transferred to the surface modifying device 30 of the first processing block G1 by the wafer transfer device 61. In the surface modifying device 30, oxygen gas as a process gas is excited, converted to plasma and ionized under a specified depressurized atmosphere. The oxygen ions thus generated are irradiated on the front surface W_{U1} of the upper wafer W_{U}, whereby the front surface W_{U1} is plasma-processed. Thus, the front surface W_{U1} of the upper wafer W_{U} is modified (Step S1 in FIG. 17).

Next, the upper wafer W_{U} is transferred to the surface hydrophilizing device 40 of the second processing block G2 by the wafer transfer device 61. In the surface hydrophilizing device 40, pure water is supplied onto the upper wafer W_{U} while rotating the upper wafer W_{U} held in a spin chuck. The pure water thus supplied is diffused on the front surface W_{U1} of the upper wafer W_{U}. Hydroxyl groups (silanol groups) adhere to the front surface W_{U1} of the upper wafer W_{U} modified in the surface modifying device 30, whereby the front surface W_{U1} is hydrophilized. Furthermore, the front surface W_{U1} of the upper wafer W_{U} is cleaned by the pure water (Step S2 in FIG. 17).

Then, the upper wafer W_{U} is transferred to the bonding device 41 of the second processing block G2 by the wafer transfer device 61. The upper wafer W_{U} carried into the bonding device 41 is transferred to the position adjustment mechanism 120 through the transition 110 by the wafer transfer mechanism 111. The horizontal direction orientation of the upper wafer W_{U} is adjusted by the position adjustment mechanism 120 (Step S3 in FIG. 17).

Thereafter, the upper wafer W_{U} is delivered from the position adjustment mechanism 120 to the holding arm 131 of the inverting mechanism 130. Subsequently, in the transfer region T1, the holding arm 131 is inverted to thereby invert the front and rear surfaces of the upper wafer W_{U} (Step S4 in FIG. 17). That is to say, the front surface W_{U1} of the upper wafer W_{U} is oriented downward.

Thereafter, the holding arm 131 of the inverting mechanism 130 rotates about the first drive unit 134 and moves to below the upper chuck 140. Then, the upper wafer W_{U} is delivered from the inverting mechanism 130 to the upper chuck 140. The rear surface W_{U2} of the upper wafer W_{U} is adsorptively held by the upper chuck 140 (Step S5 in FIG. 17). More specifically, the vacuum pump 196 is operated to vacuum-draw the suction region 193 from the suction holes 194. Thus, the upper wafer W_{U} is adsorptively held by the upper chuck 140.

During the time when the processing of steps S1 to S5 is performed with respect to the upper wafer W_{U}, processing with respect to the lower wafer W_{L} is also performed. First, the lower wafer W_{L} is taken out from the cassette C_{L} by the wafer transfer device 22 and is transferred to the transition device 50 of the processing station 3.

Next, the lower wafer W_{L} is transferred to the surface modifying device 30 by the wafer transfer device 61. The front surface W_{U} of the lower wafer W_{L} is modified in the surface modifying device 30 (Step S6 in FIG. 17). The modification of the front surface W_{L1} of the lower wafer W_{L} performed in Step S6 is the same as the modification performed in Step S1.

Thereafter, the lower wafer W_{L} is transferred to the surface hydrophilizing device 40 by the wafer transfer device 61. The front surface W_{L1} of the lower wafer W_{L} is hydrophilized and cleaned in the surface hydrophilizing device 40 (Step S7 in FIG. 17). The hydrophilizing and cleaning of the front surface W_{L1} of the lower wafer W_{L} performed in Step S7 is the same as the hydrophilizing and cleaning performed in Step S2.

Thereafter, the lower wafer W_{L} is transferred to the bonding device 41 by the wafer transfer device 61. The lower wafer W_{L} carried into the bonding device 41 is transferred to the position adjustment mechanism 120 through the transition 110 by the wafer transfer mechanism 111. The horizontal direction orientation of the lower wafer W_{L} is adjusted by the position adjustment mechanism 120 (Step S8 in FIG. 17).

Thereafter, the lower wafer W_{L} is transferred to the lower chuck 141 by the wafer transfer mechanism 111. The rear surface W_{L2} of the lower wafer W_{L} is adsorptively held by the lower chuck 141 (Step S9 in FIG. 17). More specifically, the vacuum pump 216 is operated to vacuum-draw the suction region 213 from the suction holes 214, whereby the lower wafer W_{L} is adsorptively held by the lower chuck 141.

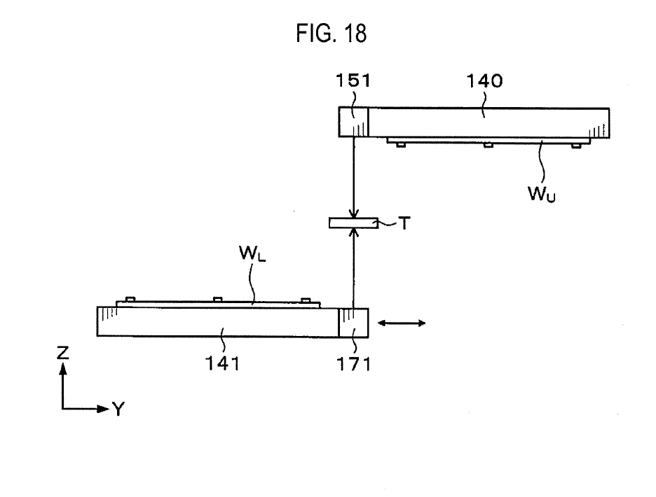

Next, as shown in FIG. 18, the horizontal positions of the upper image pickup unit 151 and the lower image pickup unit 171 are adjusted (Step S10 in FIG. 17).

In Step S10, the lower chuck 141 is moved in the horizontal direction (in the X-direction and the Y-direction) by the first lower chuck moving unit 170 and the second lower chuck moving unit 179 such that the lower image pickup unit 171 is positioned substantially below the upper image pickup unit 151. The visible light camera 153 of the upper image pickup unit 151 and the visible light camera 172 of the lower image pickup unit 171 identify a common target T. The horizontal position of the lower image pickup unit 171 is finely adjusted such that the horizontal positions of the upper image pickup unit 151 and the lower image pickup unit 171 coincide with each other. At this time, it is only necessary to move the lower image pickup unit 171 because the upper image pickup unit 151 is fixed to the processing vessel 100. This makes it possible to appropriately adjust the horizontal positions of the upper image pickup unit 151 and the lower image pickup unit 171.

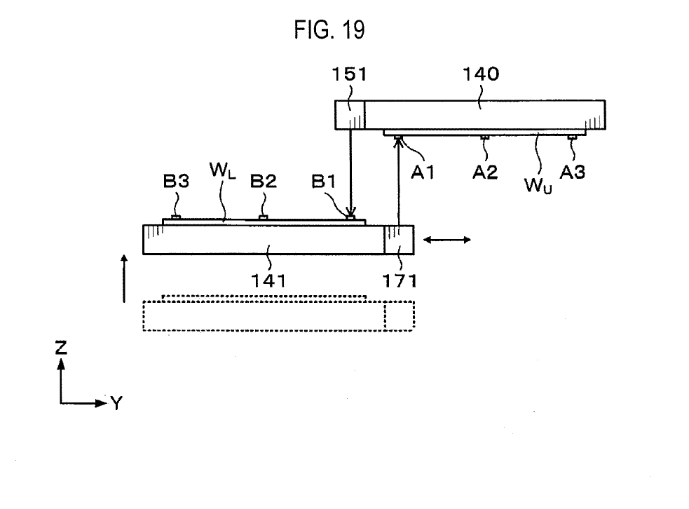

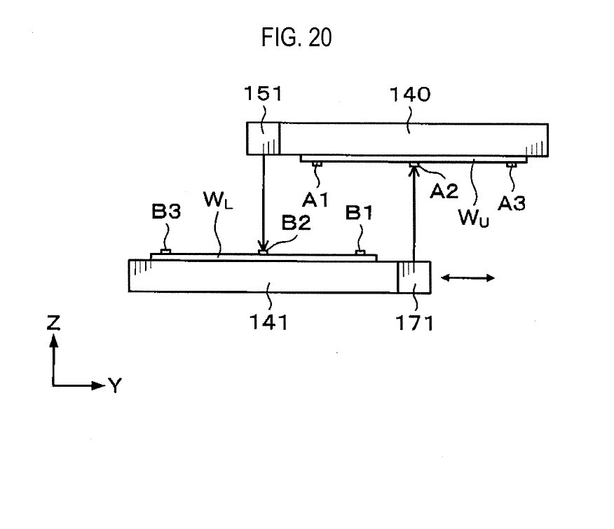

Next, as shown in FIGS. 19 and 20, the lower chuck 141 is moved vertically upward by the first lower chuck moving unit 170, and then the horizontal positions of the upper chuck 140 and the lower chuck 141 are adjusted to thereby adjust the horizontal positions of the upper wafer W_{U} held in the upper chuck 140 and the lower wafer W_{L} held in the lower chuck 141 (Steps S11 and S12 in FIG. 17).

A plurality of, e.g., three, predetermined reference points A1 to A3 are defined on the front surface W_{U1} of the upper wafer W_{U}. Similarly, a plurality of, e.g., three, predetermined reference points B1 to B3 are defined on the front surface W_{L1} of the lower wafer W_{L}. The reference points A1 and A3 and the reference points B1 and B3 are reference points of the outer peripheral portions of the upper wafer W_{U} and the lower wafer W_{L}, respectively. The reference points A2 and B2 are reference points of the central portions of the upper wafer W_{U} and the lower wafer W_{L}, respectively. For example, specific patterns formed on the upper wafer W_{U} and the lower wafer W_{L} are used as the reference points A1 to A3 and the reference points B1 to B3.

In Step S11, the lower chuck 141 is moved in the horizontal direction (in the X-direction and the Y-direction) by the first lower chuck moving unit 170 and the second lower chuck moving unit 179. Images of three points of the outer peripheral portion of the front surface W_{U} of the lower wafer W_{L} are picked up by the macro lens 159 of the visible light camera 153 of the upper image pickup unit 151. The control unit 70 measures the horizontal positions of three points based on the picked-up images and calculates the horizontal position of the central portion of the front surface W_{L1} of the lower wafer W_{L} based on the measurement result. Thereafter, the lower chuck 141 is moved in the horizontal direction, and an image of the central portion (the centrally-located chip) of the front surface W_{L1} of the lower wafer W_{L} is picked up. Subsequently, the lower chuck 141 is further moved in the horizontal direction, and an image of the chip located adjacent to the centrally-located chip is picked up. Then, the control unit 70 calculates the slope of the lower wafer W_{L} based on the image of the centrally-located chip and the image of the chip located adjacent to the centrally-located chip. By acquiring the horizontal position of the central portion of the lower wafer W_{L} and the slope of the lower wafer W_{L} in this way, it is possible to acquire approximate coordinates of the lower wafer W_{L}. The horizontal position of the lower chuck 141 is roughly adjusted based on the approximate coordinates of the lower wafer W_{L}. The horizontal positions of the upper wafer W_{U} and the lower wafer W_{L} are roughly adjusted in the aforementioned manner.

The rough adjustment of the horizontal positions in Step S11 is performed into such positions where, at least in Step S12 to be described below, the upper image pickup unit 151 can pick up the images of the reference points B1 to B3 of the lower wafer W_{L} and the lower image pickup unit 171 can pick up the images of the reference points A1 to A3 of the upper wafer W_{U}.

In Step S12 performed subsequently, the lower chuck 141 is moved in the horizontal direction (in the X-direction and the Y-direction) by the first lower chuck moving unit 170 and the second lower chuck moving unit 179. The images of the reference points B1 to B3 of the front surface W_{L1} of the lower wafer W_{L} are sequentially picked up using the micro lens 155 of the visible light camera 153 of the upper image pickup unit 151. At the same time, the images of the reference points A1 to A3 of the front surface W_{U1} of the upper wafer W_{U} are sequentially picked up using the micro lens 174 of the visible light camera 172 of the lower image pickup unit 171. FIG. 19 illustrates how to pick up the image of the reference point B1 of the lower wafer W_{L} using the upper image pickup unit 151 and how to pick up the image of the reference point A1 of the front surface W_{U1} of the upper wafer W_{U} using the lower image pickup unit 171.

FIG. 20 illustrates how to pick up the image of the reference point B2 of the lower wafer W_{L} using the upper image pickup unit 151 and how to pick up the image of the reference point A2 of the front surface W_{U1} of the upper wafer W_{U} using the lower image pickup unit 171. The visible-light images thus picked up are output to the control unit 70. Based on the visible-light images picked up by the upper image pickup unit 151 and by the lower image pickup unit 171, the control unit 70 controls the first lower chuck moving unit 170 and the second lower chuck moving unit 179 to move the lower chuck 141 to a position where the reference points A1 to A3 of the upper wafer W_{U} coincide respectively with the reference points B1 to B3 of the lower wafer W_{L}. In this way, the horizontal positions of the upper wafer W_{U} and the lower wafer W_{L} are finely adjusted. At this time, it is only necessary to move the lower chuck 141 because the upper chuck 140 is fixed to the processing vessel 100. Thus, it is possible to appropriately adjust the horizontal positions of the upper chuck 140 and the lower chuck 141 and to appropriately adjust the horizontal positions of the upper wafer W_{U} and the lower wafer W_{L}.

During the fine adjustment of the horizontal positions performed in Step S12, the orientation of the lower chuck 141 is also finely adjusted by moving the lower chuck 141 in the horizontal direction (in the X-direction and the Y-direction) as described above and by rotating the lower chuck 141 using the first lower chuck moving unit 170.

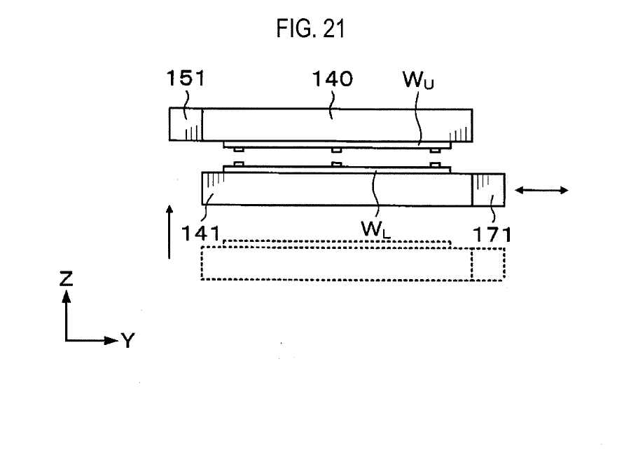

Thereafter, as shown in FIG. 21, the lower chuck 141 is moved vertically upward by the first lower chuck moving unit 170, whereby the vertical positions of the upper chuck 140 and the lower chuck 141 are adjusted to thereby adjust the vertical positions of the upper wafer W_{U} held in the upper chuck 140 and the lower wafer W_{L} held in the lower chuck 141 (Step S13 in FIG. 17). At this time, the gap between the front surface W_{L1} of the lower wafer W_{L} and the front surface W_{U1} of the upper wafer W_{U} is set equal to a predetermined distance, e.g., 50 μm to 200 μm.

Next, a process of bonding the upper wafer W_{U} held in the upper chuck 140 and the lower wafer W_{L} held in the lower chuck 141 is performed.

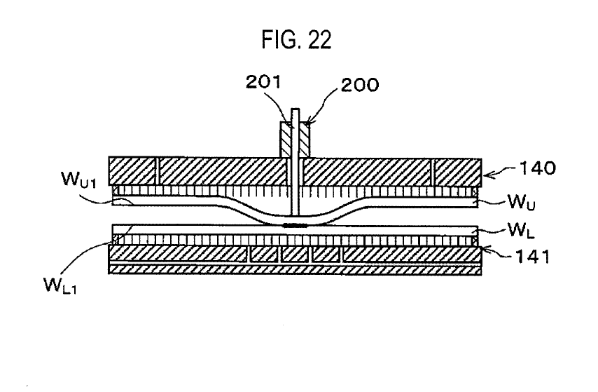

First, as shown in FIG. 22, the pressing pin 201 of the pressing member 200 is moved down, thereby moving the upper wafer W_{U} downward while pressing the central portion of the upper wafer W_{U}. At this time, a load of, e.g., 200 g, which enables the pressing pin 201 to move 70 μm with the upper wafer W_{U} removed, is applied to the pressing pin 201. By virtue of the pressing member 200, the central portion of the upper wafer W_{U} is brought into contact with, and pressed against, the central portion of the lower wafer W_{L} (Step S14 in FIG. 17). Since the suction holes 194 of the upper chuck 140 are formed in the outer peripheral portion of the suction region 193, it is possible for the upper chuck 140 to hold the outer peripheral portion of the upper wafer W_{U} even when the pressing member 200 presses the central portion of the upper wafer W_{U}.

Then, bonding begins to occur between the central portion of the upper wafer W_{U} and the central portion of the lower wafer W_{L} pressed against each other (see the portion indicated by a thick line in FIG. 22). That is to say, since the front surface W_{U1} of the upper wafer W_{U} and the front surface W_{L1} of the lower wafer W_{L} are previously modified in Steps S1 and S6, a Van der Waals force (an intermolecular force) is generated between the front surfaces W_{U1} and W_{L1}, whereby the front surfaces W_{U1} and W_{L1} are bonded to each other. Furthermore, since the front surface W_{U1} of the upper wafer W_{U} and the front surface W_{L1} of the lower wafer W_{L} are previously hydrophilized in Steps S2 and S7, the hydrophilic groups existing between the front surfaces W_{U1} and W_{L1} are hydrogen-bonded (by an intermolecular force), whereby the front surfaces W_{U1} and W_{L1} are strongly bonded to each other.

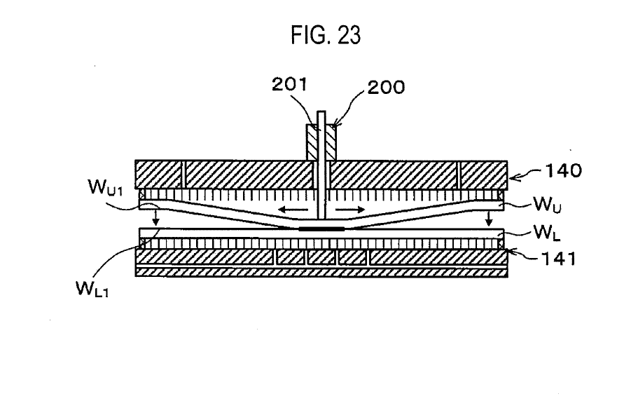

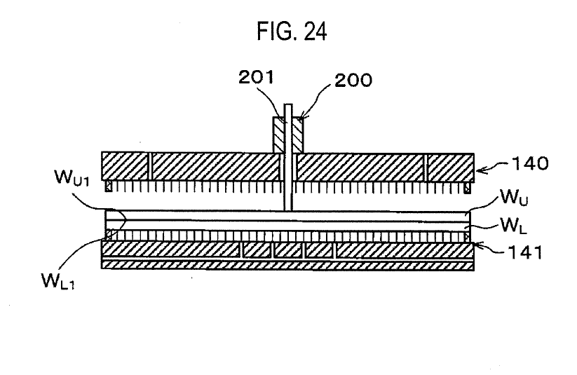

Thereafter, as shown in FIG. 23, the vacuum-drawing of the upper wafer W_{U} in the suction region 193 is stopped by stopping the operation of the vacuum pump 196 in a state in which the central portion of the upper wafer W_{U} and the central portion of the lower wafer W_{L} are pressed against each other by the pressing member 200. By doing so, the upper wafer W_{U} is dropped onto the lower wafer W_{L}. Since the rear surface W_{U2} of the upper wafer W_{U} is supported by the pins 191, the upper wafer W_{U} is easily detached from the upper chuck 140 upon releasing the vacuum-drawing of the upper wafer W_{U} performed by the upper chuck 140. The vacuum-drawing of the upper wafer W_{U} is stopped from the central portion of the upper wafer W_{U} toward the outer peripheral portion thereof. Thus, the upper wafer W_{U} is gradually dropped onto, and gradually brought into contact with, the lower wafer W_{L}, whereby the bonding area between the front surfaces W_{U1} and W_{L1} is gradually widened by a Van der Waals force and hydrogen bonding. Consequently, as shown in FIG. 24, the front surface W_{U1} of the upper wafer W_{U} and the front surface W_{U1} of the lower wafer W_{L} make contact with each other over the entire area thereof, whereby the upper wafer W_{U} and the lower wafer W_{L} are bonded to each other (Step S15 in FIG. 17).

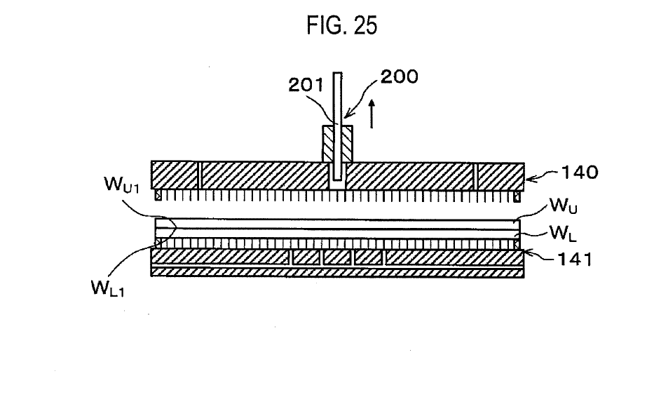

Thereafter, as shown in FIG. 25, the pressing pin 201 of the pressing member 200 is moved up to the upper chuck 140. Moreover, the operation of the vacuum pump 216 is stopped and the vacuum-drawing of the lower wafer W_{L} in the suction region 213 is stopped such that the lower chuck 141 ceases to adsorptively hold the lower wafer W_{L}. Since the rear surface W_{L2} of the lower wafer W_{L} is supported by the pins 211, the lower wafer W_{L} is easily detached from the lower chuck 141 upon releasing the vacuum-drawing of the lower wafer W_{L} performed by the lower chuck 141.

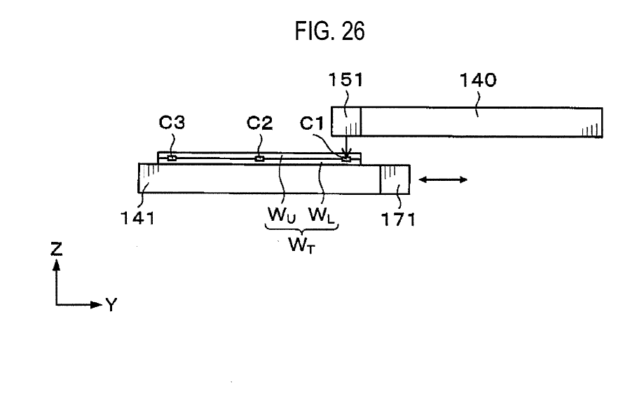

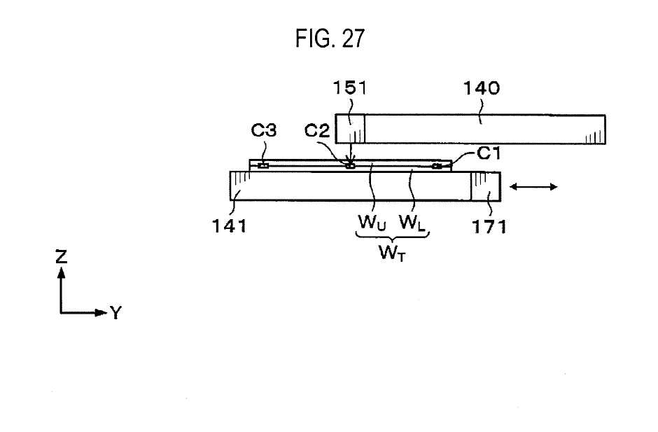

Next, as shown in FIGS. 26 and 27, the overlapped wafer W_{T} obtained by bonding the upper wafer W_{U} and the lower wafer W_{U} is inspected (Step S16 in FIG. 17). On the bonding surface of the wafers W_{U} and W_{U} in the overlapped wafer W_{T}, the reference points where the reference points A1 to A3 of the upper wafer W_{U} and the reference points B1 to B3 of the lower wafer W_{L} make contact with each other will be designated by C1 to C3.

In Step S16, while moving the lower chuck 141 in the horizontal direction (in the X-direction and the Y-direction) by the first lower chuck moving unit 170 and the second lower chuck moving unit 179, the images of the reference points C1 to C3 located within the overlapped wafer W_{T} are sequentially picked up using the infrared camera 152 of the upper image pickup unit 151. At this time, since the infrared rays are transmitted through the overlapped wafer W_{T}, the infrared camera 152 can pick up the images of the reference points C1 to C3 located within the overlapped wafer W_{T}. FIG. 26 illustrates how to pick up the image of the reference point C1 in the overlapped wafer W_{T} by the upper image pickup unit 151. FIG. 27 illustrates how to pick up the image of the reference point C2 in the overlapped wafer W_{T} by the upper image pickup unit 151. The infrared images thus picked up are output to the control unit 70. The control unit 70 performs inspection of the overlapped wafer W_{T} based on the infrared images picked up by the infrared camera 152. That is to say, inspection is performed as to whether the reference point A1 and the reference point B1 coincide with each other in the reference point C1. Similarly, with respect to other reference points C2 and C3, inspection is performed as to whether the reference points A2 and A3 coincide with the reference points B2 and B3, respectively. In this way, inspection is made as to whether, in the overlapped wafer W_{T}, the upper wafer W_{U} and the lower wafer W_{L} are bonded to each other in a suitable position.

In the inspection of the overlapped wafer W_{T} performed in Step S16, the coincidence of the reference points A1 to A3 and the reference points B1 to B3 includes not only a case where the reference points completely coincide with each other but also a case where the positional deviation of the respective reference points falls within a desired range.

Thereafter, the horizontal positions of the upper chuck 140 and the lower chuck 141 are adjusted based on the inspection results of Step S16 (Step S17 in FIG. 17). That is to say, for the subsequent processing on the wafers W_{U} and W_{L}, the upper chuck 140 and the lower chuck 141 are feedback controlled.

In Step S17, the horizontal positions of the upper chuck 140 and the lower chuck 141 are not adjusted if the inspection results are normal. On the other hand, if the inspection results are abnormal, namely if the upper wafer W_{U} and the lower wafer W_{L} are bonded in a horizontally deviated state, a correction value corresponding to the deviation is stored in the control unit 70. Then, after Step S12 is performed with respect to the next wafers W_{U} and W_{L}, the lower chuck 141 is moved just as much as the correction value by the first lower chuck moving unit 170 and the second lower chuck moving unit 179. By doing so, the horizontal position of the lower chuck 141 is appropriately adjusted. This makes it possible for the bonding process of the wafers W_{U} and W_{L} to be performed subsequently.

Thereafter, the overlapped wafer W_{T} subjected to the inspection is transferred to the transition device 51 by the wafer transfer device 61 and is then transferred to the cassette C_{T} located on one of the specified cassette mounting boards 11 by the wafer transfer device 22 of the carry-in/carry-out station 2. As a result, the bonding process of the wafers W_{U} and W_{L} is finished.

According to the embodiment described above, the infrared rays are transmitted through the overlapped wafer W_{T} when inspecting the overlapped wafer W_{T} in Step S16. Thus, the images of the reference points C1 to C3 can be picked up by the infrared camera 152 of the upper image pickup unit 151. As a result, in Step S17 to be performed subsequently, the upper chuck 140 and the lower chuck 141 can be feedback controlled based on the inspection results such that, in the overlapped wafer W_{T}, the reference points A1 to A3 of the upper wafer W_{U} coincide with the reference points B1 to B3 of the lower wafer W_{L}. Accordingly, it is possible to appropriately adjust the horizontal positions of the upper chuck 140 and the lower chuck 141. This makes it possible to appropriately perform the subsequent bonding process of the wafers W_{U} and W_{L}.

As mentioned above, the inspection of the overlapped wafer W_{T} can be performed within the bonding device 41. There is no need to additionally install an inspection device outside the bonding device 41. It is therefore possible to save the device manufacturing cost. In addition, since the overlapped wafer W_{T} can be inspected just after the wafers W_{U} and W_{L} are bonded to each other, it is possible to feed back the inspection results to the subsequent bonding process at an appropriate timing. This enhances the accuracy of the bonding process.

The upper image pickup unit 151 and the lower image pickup unit 171 are provided with the visible light cameras 153 and 172, respectively. Therefore, in Steps S10 to S12, the images of the lower wafer W_{L} and the upper wafer W_{U} can be picked up by the visible light cameras 153 and 172. By doing so, the horizontal positions of the upper chuck 140 and the lower chuck 141 can be appropriately adjusted based on the visible light images thus picked up. Accordingly, it is possible to appropriately perform the bonding process of the upper wafer W_{U} and the lower wafer W_{L} in Steps S14 and S15.

In addition, since the upper image pickup unit 151 and the lower image pickup unit 171 are respectively provided with the micro lens 155 and 174 and the macro lens 159 and 176, it is possible to adjust, in a stepwise manner, the horizontal positions of the upper chuck 140 and the lower chuck 141 in Steps S11 and S12. Accordingly, it is possible to efficiently adjust the horizontal positions of the upper chuck 140 and the lower chuck 141.

The upper chuck 140 is fixed to the processing vessel 100, and the upper image pickup unit 151 is also fixed to the processing vessel 100. Thus, there is no possibility that the upper chuck 140 and the upper image pickup unit 151 are moved over time. In Step S10, it is only necessary to move the lower image pickup unit 171 because the upper image pickup unit 151 is fixed to the processing vessel 100. This makes it possible to appropriately adjust the horizontal positions of the upper image pickup unit 151 and the lower image pickup unit 171. In Steps S11 and S12, it is only necessary to move the lower chuck 141 because the upper chuck 140 is fixed to the processing vessel 100. This makes it possible to appropriately adjust the horizontal positions of the upper chuck 140 and the lower chuck 141. That is to say, it is possible to enhance the accuracy of the adjustment of the horizontal positions of the upper chuck 140 and the lower chuck 141.

The bonding system 1 includes not only the bonding device 41 but also the surface modifying device 30 for modifying the front surfaces W_{U1} and W_{U} of the wafers W_{U} and W_{L} and the surface hydrophilizing device 40 for hydrophilizing and cleaning the front surfaces W_{U1} and W_{L1}. Thus, the bonding of the wafers W_{U} and W_{L} can be efficiently performed within one system. Accordingly, it is possible to increase the throughput of the wafer bonding process.

The bonding device 41 of the aforementioned embodiment may be used in a case where three or more wafers are bonded together. Description will now be made on a case where another wafer W_{Z} is bonded to the overlapped wafer W_{T1} bonded in the aforementioned embodiment. The overlapped wafer W_{T1} may be made thinner by polishing the rear surface W_{U2} of the upper wafer W_{U} or the rear surface W_{L2} of the lower wafer W_{L}. In the present embodiment, the wafer W_{Z} is a first substrate and the overlapped wafer W_{T1} is a second substrate.

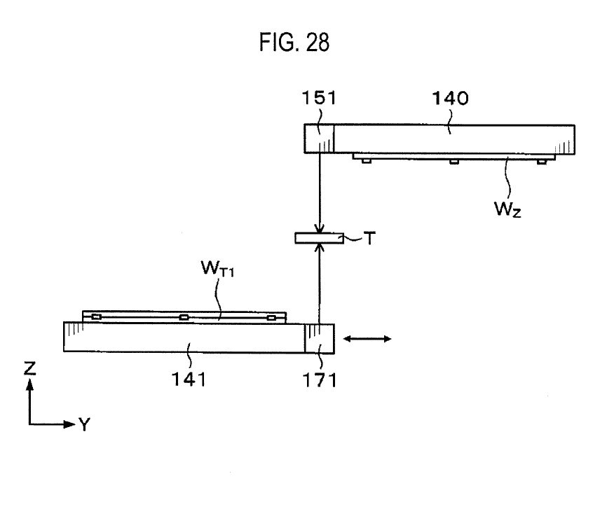

The wafer W_{Z} is subjected to Step S1 to S5 described above. The wafer W_{Z} is adsorptively held by the upper chuck 140. On the other hand, the overlapped wafer W_{T1} is subjected to Steps S6 to S9 described above. The overlapped wafer W_{T1} is adsorptively held by the lower chuck 141. Thereafter, in Step S10 described above, the horizontal positions of the upper image pickup unit 151 and the lower image pickup unit 171 are adjusted as shown in FIG. 28.

Performed next is Step S11 where the horizontal positions of the upper chuck 140 and the lower chuck 141 are roughly adjusted using the macro lens 159 of the visible light camera 153 of the upper image pickup unit 151 and the macro lens 176 of the visible light camera 172 of the lower image pickup unit 171.

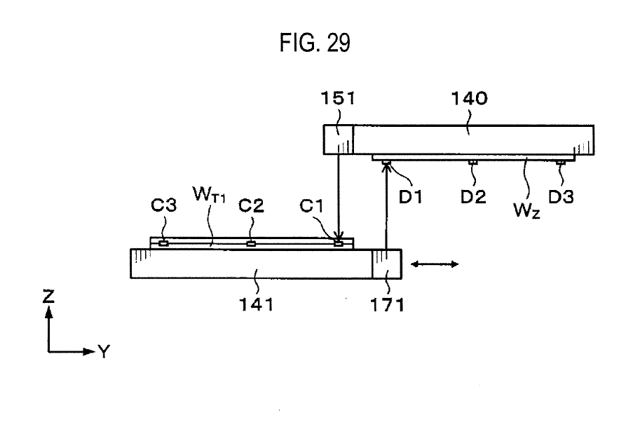

Next, in Step S12, the horizontal positions of the upper chuck 140 and the lower chuck 141 are adjusted as shown in FIG. 29. Reference points C1 to C3 are defined within the overlapped wafer W_{T1}. Predetermined reference points D1 to D3 are also defined on the front surface of the wafer W_{Z}.

In Step S12, while moving the lower chuck 141 in the horizontal direction (in the X-direction and the Y-direction) by the first lower chuck moving unit 170 and the second lower chuck moving unit 179, the images of the reference points C1 to C3 located within the overlapped wafer W_{T1} are sequentially picked up using the infrared camera 152 of the upper image pickup unit 151. At this time, since the infrared rays are transmitted through the overlapped wafer W_{T1}, the infrared camera 152 can pick up the images of the reference points C1 to C3 located within the overlapped wafer W_{T1}. At the same time, while moving the lower chuck 141 in the horizontal direction, the images of the reference points D1 to D3 on the front surface of the wafer W_{Z} are sequentially picked up using the micro lens 174 of the visible light camera 172 of the lower image pickup unit 171. FIG. 29 illustrates how to pick up the image of the reference point C1 of the overlapped wafer W_{T1} by the upper image pickup unit 151 and how to pick up the image of the reference point D1 of the wafer W_{Z} by the lower image pickup unit 171. The infrared images and the visible light images thus picked up are output to the control unit 70. The control unit 70 controls the first lower chuck moving unit 170 and the second lower chuck moving unit 179, based on the infrared images picked up by the upper image pickup unit 151 and the visible light images picked up by the lower image pickup unit 171, to adjust the horizontal position of the lower chuck 141 such that the reference points C1 to C3 of the overlapped wafer W_{T1} coincide respectively with the reference points D1 to D3 of the wafer W_{Z}. In this way, the horizontal positions of the upper chuck 140 and the lower chuck 141 are adjusted and the horizontal positions of the wafer W_{Z} and the overlapped wafer W_{T1} are adjusted.

Thereafter, Step S13 described above is performed to adjust the vertical positions of the upper chuck 140 and the lower chuck 141. Then, Steps S14 and S15 described above are performed to carry out the bonding process of the wafer W_{Z} held in the upper chuck 140 and the overlapped wafer W_{T1} held in the lower chuck 141.

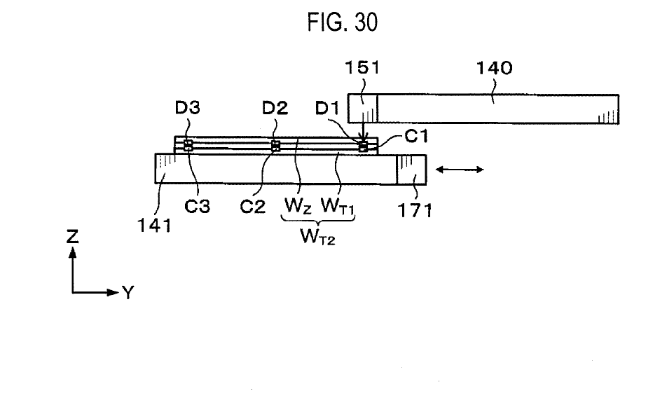

Next, in Step S16, an overlapped wafer W_{T2} obtained by bonding the wafer W_{Z} and the overlapped wafer W_{T1} is inspected as shown in FIG. 30. In this case, while moving the lower chuck 141 in the horizontal direction (in the X-direction and the Y-direction) by the first lower chuck moving unit 170 and the second lower chuck moving unit 179, the images of the reference points D1 to D3 (the reference points C1 to C3) located within the overlapped wafer W_{T2} are sequentially picked up using the infrared camera 152 of the upper image pickup unit 151. At this time, since the infrared rays are transmitted through the overlapped wafer W_{T2}, the infrared camera 152 can pick up the images of the reference points D1 to D3 located within the overlapped wafer W_{T2}. If the reference points D1 to D3 and the reference points C1 to C3 are deviated from each other in the horizontal direction, the infrared camera 152 picks up the images of the reference points C1 to C3. FIG. 30 illustrates how to pick up the image of the reference point D1 of the overlapped wafer W_{T2} by the upper image pickup unit 151. The infrared images thus picked up are output to the control unit 70. The control unit 70 performs inspection on the overlapped wafer W_{T2} based on the infrared images picked up by the infrared camera 152. That is to say, inspection is performed as to whether the reference points D1 and C1 coincide with each other. Similarly, inspection is performed as to whether the reference points D2 and D3 coincide with the reference points C2 and C3, respectively. In this way, inspection is made as to whether, in the overlapped wafer W_{T2}, the wafer W_{Z} and the overlapped wafer W_{T1} are bonded to each other in a suitable position.

Thereafter, based on the inspection results of Step S16, Step S17 described above is performed to adjust the horizontal positions of the upper chuck 140 and the lower chuck 141. That is to say, for the subsequent processing on the wafers W_{U} and W_{L}, the upper chuck 140 and the lower chuck 141 are feedback controlled.

According to the present embodiment, when adjusting the horizontal positions of the upper chuck 140 and the lower chuck 141 in Step S12, the infrared rays are transmitted through the overlapped wafer W_{T1}. Therefore, the infrared camera 152 of the upper image pickup unit 151 can pick up the images of the reference points C1 to C3 located within the overlapped wafer W_{T1}. On the other hand, the images of the reference points D1 to D3 of the wafer W_{Z} can be picked up using the visible light camera 172 of the lower image pickup unit 171. Accordingly, it is possible to appropriately adjust the horizontal positions of the upper chuck 140 and the lower chuck 141. Thereafter, in Steps S14 and S15, the bonding process of the wafer W_{Z} and the overlapped wafer W_{T1} can be appropriately performed.

Even when inspecting the overlapped wafer W_{T2} in Step S16, the infrared rays are transmitted through the overlapped wafer W_{T2}. Thus, the images of the reference points D1 to D3 located within the overlapped wafer W_{T2} can be picked up by the infrared camera 152 of the upper image pickup unit 151. By doing so, in Step S17, the upper chuck 140 and the lower chuck 141 can be feedback controlled based on the inspection results. Accordingly, it is possible to appropriately adjust the horizontal positions of the upper chuck 140 and the lower chuck 141. This makes it possible to appropriately perform the bonding process of the subsequent wafers W_{U} and W_{L}.

In the aforementioned embodiment, description has been made on a case where three wafers are bonded in the bonding device 41. However, four or more wafers may be bonded in the bonding device 41.

In the bonding device 41 of the aforementioned embodiment, the sensor 154 of the infrared camera 152 and the sensor 157 of the visible light camera 153 are independently installed in the upper image pickup unit 151. Alternatively, a sensor capable acquiring both an infrared image and a visible light image may be installed in common.

Although the infrared camera 152 is installed in the upper image pickup unit 151 in the aforementioned embodiment, it may be possible to install the infrared camera 152 in the lower image pickup unit 171. Alternatively, two infrared cameras 152 may be separately installed in the upper image pickup unit 151 and the lower image pickup unit 171. If the infrared cameras 152 are installed in the upper image pickup unit 151 and in the lower image pickup unit 171, both the upper chuck 140 and the lower chuck 141 can hold an overlapped wafer obtained by laminating a plurality of wafers. Thus, the degree of freedom of the bonding process is enhanced.

In the bonding device 41 of the aforementioned embodiment, the upper chuck 140 is fixed to the processing vessel 100 and the lower chuck 141 is moved in the horizontal direction and the vertical direction. In contrast, the upper chuck 140 may be moved in the horizontal direction and the vertical direction and the lower chuck 141 may be fixed to the processing vessel 100. Alternatively, both the upper chuck 140 and the lower chuck 141 may be moved in the horizontal direction and the vertical direction.

In the bonding system 1 of the aforementioned embodiment, after the wafers W_{U} and W_{L} are bonded by the bonding device 41, the overlapped wafer W_{T} thus bonded may be heated (annealed) to a predetermined temperature. By heating the overlapped wafer W_{T} in this way, it is possible to strongly join the bonding interface.

According to the present disclosure, since the infrared rays are transmitted through the overlapped wafer, the infrared camera can pick up the images of the reference points located within the overlapped wafer.

In a case of bonding three or more wafers together, for example, bonding a single wafer as a first substrate and an overlapped wafer a second substrate together, reference points located within the second substrate can be picked up using an infrared camera. In addition, reference points on the front surface of the first substrate can be picked up using various types of cameras. In this case, the horizontal positions of the first holding unit and the second holding unit can be appropriately adjusted based on thus picked-up images such that, the reference points of the first substrate and the reference points of the second substrate coincide with each other.

In addition, in a case of inspecting an overlapped wafer obtained by bonding the first substrate and the second substrate together, for example, reference points located within the overlapped wafer can be picked up using the infrared camera. In this case, the first holding unit and the second holding unit can be feedback controlled based on the inspection results such that, in the overlapped wafer, the reference points of the first substrate coincide with the reference points of the second substrate. Accordingly, it is possible to appropriately adjust the horizontal positions of the first holding unit and the second holding unit.

In addition, the inspection of the overlapped wafer can be performed within the bonding device. There is no need to additionally install an inspection device outside the bonding device. It is therefore possible to save the device manufacturing cost. In addition, since the overlapped wafer can be inspected just after the wafers are bonded to each other, it is possible to feed back the inspection results to the subsequent bonding process at an appropriate timing. This enhances the accuracy of the bonding process.

According to the present disclosure, it is possible to appropriately adjust the horizontal positions of a first holding unit for holding a first substrate and a second holding unit for holding a second substrate and to appropriately perform a bonding process of substrates.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures. The present disclosure may be applied to a case where the substrate is not a wafer but another substrate such as a FPD (Flat Panel Display), a mask reticle for a photo mask or the like.

What is claimed is:

1. A bonding device for bonding substrates together, comprising:
a first holding unit configured to hold a first substrate on a lower surface of the first holding unit;
a second holding unit located below the first holding unit and configured to hold a second substrate on an upper surface of the second holding unit;
a moving mechanism configured to move the first holding unit or the second holding unit in a horizontal direction and a vertical direction;
a first image pickup unit located in the first holding unit and configured to pick up an image of the second substrate held in the second holding unit; and
a second image pickup unit located in the second holding unit and configured to pick up an image of the first substrate held in the first holding unit,
at least one of the first image pickup unit and the second image pickup unit including an infrared camera.

2. The bonding device of claim 1, wherein each of the first image pickup unit and the second image pickup unit includes a visible light camera.

3. The bonding device of claim 2, wherein the infrared camera and the visible light camera include a common micro lens, and the visible light camera further includes a macro lens.

4. The bonding device of claim 1, further comprising:
a control unit configured to control operations of the moving mechanism, the first image pickup unit and the second image pickup unit,
the control unit being configured to control the first image pickup unit to pick up an image of the second substrate not yet bonded, to control the second image pickup unit to pick up an image of the first substrate not yet bonded, and then to control the moving mechanism to adjust horizontal positions of the first holding unit and the second holding unit based on the image picked up by the first image pickup unit and the image picked up by the second image pickup unit.

5. The bonding device of claim 1, further comprising:
a control unit configured to control operations of the moving mechanism, the first image pickup unit and the second image pickup unit,
the control unit being configured to control the infrared camera to pick up an image of an overlapped substrate obtained by bonding the first substrate and the second substrate so as to inspect the overlapped substrate, and then to control the moving mechanism to adjust horizontal positions of the first holding unit and the second holding unit based on an inspection result.

6. The bonding device of claim 1, wherein the first holding unit, the second holding unit, the moving mechanism, the first image pickup unit and the second image pickup unit are located within a processing vessel, the first holding unit being fixed within the processing vessel, and the moving mechanism configured to move the second holding unit in the horizontal direction and the vertical direction.

7. A bonding method for bonding substrates with a bonding device which includes a first holding unit configured to hold a first substrate on a lower surface of the first holding unit, a second holding unit located below the first holding unit and configured to hold a second substrate on an upper surface of the second holding unit, a moving mechanism configured to move the first holding unit or the second holding unit in a horizontal direction and a vertical direction, a first image pickup unit located in the first holding unit and configured to pick up an image of the second substrate held in the second holding unit, and a second image pickup unit located in the second holding unit and configured to pick up an image of the first substrate held in the first holding unit, at least one of the first image pickup unit and the second image pickup unit including an infrared camera, the method comprising:
picking up images of the second substrate not yet bonded and the first substrate not yet bonded by the first image pickup unit and the second image pickup unit, respectively; and
adjusting horizontal positions of the first holding unit and the second holding unit by the moving mechanism based on the images thus picked up.

8. The bonding method of claim 7, wherein each of the first image pickup unit and the second image pickup unit includes a visible light camera, and
wherein, in picking up images of the second substrate not yet bonded and the first substrate not yet bonded, the infrared camera picks up an image of the first substrate made up of a plurality of substrates or an image of the second substrate made up of a plurality of substrates, and the visible light camera picks up an image of the first substrate made up of a single substrate or an image of the second substrate made up of a single substrate.

9. The bonding method of claim 8, wherein the infrared camera and the visible light camera include a common micro lens, and the visible light camera further includes a macro lens,
wherein, prior to picking up images of the second substrate not yet bonded and the first substrate not yet bonded, an image of the second substrate is picked up by the macro lens of the first image pickup unit and then the horizontal positions of the first holding unit and the second holding unit are adjusted by the moving mechanism,
wherein, in picking up images of the second substrate not yet bonded and the first substrate not yet bonded, images of the first substrate and the second substrate are picked up by the micro lens, and
wherein, in adjusting horizontal positions of the first holding unit and the second holding unit, the horizontal positions of the first holding unit and the second holding unit are adjusted by the moving mechanism.

10. The bonding method of claim 7, further comprising:
after adjusting horizontal positions of the first holding unit and the second holding unit, bonding the first substrate held in the first holding unit and the second substrate held in the second holding unit to each other to form an overlapped substrate;
inspecting the overlapped substrate by picking up an image of the overlapped substrate by the infrared camera; and then
adjusting the horizontal positions of the first holding unit and the second holding unit by the moving mechanism based on an inspection result.

11. A bonding method for bonding substrates with a bonding device which includes a first holding unit configured to hold a first substrate on a lower surface of the first holding unit, a second holding unit located below the first holding unit and configured to hold a second substrate on an upper surface of the second holding unit, a moving mechanism configured to move the first holding unit or the second holding unit in a horizontal direction and a vertical direction, a first image pickup unit located in the first holding unit and configured to pick up an image of the second substrate held in the second holding unit, and a second image pickup unit located in the second holding unit and configured to pick up an image of the first substrate held in the first holding unit, at least one of the first image pickup unit and the second image pickup unit including an infrared camera, the method comprising:
obtaining an image for inspection of an overlapped substrate obtained by bonding the first substrate and the second substrate using the infrared camera; and
adjusting horizontal positions of the first holding unit and the second holding unit with the moving mechanism based on the image for inspection obtained from the infrared camera.

12. The bonding method of claim 11, wherein each of the first image pickup unit and the second image pickup unit includes a visible light camera, and the bonding method further comprises:
prior to obtaining an image for inspection of an overlapped substrate, adjusting the horizontal positions of the first holding unit and the second holding unit with the moving mechanism based on images of the second substrate not yet bonded and the first substrate not yet bonded, the image of the second substrate not yet bonded being picked up by the visible light camera of the first image pickup unit and the image of the first substrate not yet bonded being picked up by the visible light camera of the second image pickup unit.

13. The bonding method of claim 12, wherein the infrared camera and the visible light camera include a common micro lens, and the visible light camera further includes a macro lens, and
wherein, adjusting the horizontal positions of the first holding unit and the second holding unit includes:
picking up an image of the second substrate with the macro lens of the first image pickup unit and then adjusting the horizontal positions of the first holding unit and the second holding unit with the moving mechanism; and
picking up images of the second substrate and the first substrate with the micro lens of the first image pickup unit and with the micro lens of the second image pickup unit, respectively, and then adjusting the horizontal positions of the first holding unit and the second holding unit with the moving mechanism.

14. The bonding method of claim 7, wherein the first holding unit, the second holding unit, the moving mechanism, the first image pickup unit and the second image pickup unit are located within a processing vessel, the first holding unit being fixed within the processing vessel, and the moving mechanism being configured to move the second holding unit in the horizontal direction and the vertical direction.

15. The bonding method of claim 11, wherein the first holding unit, the second holding unit, the moving mechanism, the first image pickup unit and the second image pickup unit are located within a processing vessel, the first holding unit being fixed within the processing vessel, and the moving mechanism being configured to move the second holding unit in the horizontal direction and the vertical direction.
